(19) United States
(12) Patent Application Publication
(10) Pub. No.: US 2025/0079312 A1
(43) Pub. Date: Mar. 6, 2025

(54) METHODS AND STRUCTURES FOR HIGH STRENGTH DIELECTRIC IN HYBRID BONDING

(71) Applicant: Applied Materials, Inc., Santa Clara, CA (US)

(72) Inventors: Tyler Sherwood, Fonda, NY (US); Raghav Sreenivasan, Fremont, CA (US); Kun Li, Delmar, NY (US)

(73) Assignee: Applied Materials, Inc., Santa Clara, CA (US)

(21) Appl. No.: 18/460,154

(22) Filed: Sep. 1, 2023

(51) Int. Cl. H01L 23/532; H01L 21/768; H01L 23/00

(52) U.S. Cl. CPC H01L 23/53238; H01L 21/76802; H01L 21/76831; H01L 21/76877; H01L 24/08; H01L 24/80; H01L 2224/08145; H01L 2224/80895

(57) ABSTRACT

A structure for semiconductor devices having a high-dielectric constant dielectric film on the top surface of the structure can be used to form semiconductor devices that are composed of hybrid bonded structures with reduced dielectric surface area and reduced pitch for metal studs. For example, the dielectric constant of the dielectric film can be about or greater than 7 or 8. A semiconductor device can be formed by hybrid bonding the dielectric film of the structure to a dielectric film of a similar structure. A dielectric film-oxide-metal-substrate structure can be formed with the dielectric film on the top surface of the stack. A multi-material etch can be used etch features in the dielectric film and the oxide in a dielectric film-oxide-metal-substrate stack. A chemical-mechanical polishing technique can be used to precisely form the surface of the structure in preparation for hybrid bonding.

### TECHNICAL FIELD

The present technology relates to semiconductor systems, processes, and equipment. More specifically, the present technology relates to processes and semiconductor devices for hybrid bonding.

### BACKGROUND

Hybrid bonding (which can also be referred to as heterogeneous integration) is a semiconductor fabrication technique that allows for increased miniaturization of three-dimensional semiconductor device fabrication processes related to advanced node technologies requiring heterogenous integration. Hybrid bonding involves the creation of strong bonds between dies, wafers, and/or substrates without the need for adhesives or interconnect materials. However, heterogenous integration techniques can be limited by the scaling-down of pitch. As desired pitch shrinks, the dielectric surface area available for the contact bonding part of hybrid bonding also shrinks. As such, hybrid bonding systems may require a large percentage of bonding surface between dies to be dielectric. As desired pitch decreases, standard hybrid bonding techniques and systems may be incapable of adequately providing sufficient bond strength.

Thus, there is a need for improved systems and methods that can be used to improve systems for hybrid bonding as pitch shrinks. These and other needs are addressed by the present technology.

### SUMMARY

In some embodiments, a semiconductor device for hybrid bonding may include a first structure including a metal layer overlaying a substrate; a dielectric layer overlaying the metal layer and defining a set of one or more features recessed in the dielectric layer; a dielectric film overlaying the dielectric layer, the dielectric film having a dielectric constant greater than about 7; and a copper-containing material deposited within the set of one or more features.

In some embodiments, a method of forming a semiconductor device may include forming a first structure which may include forming a metal layer over a substrate; forming an dielectric layer over the metal layer; forming a dielectric film over the dielectric layer, the dielectric film having a dielectric constant greater than about 7; etching a trench in the dielectric film and dielectric layer, wherein the trench extends from a top surface of the dielectric film down to at least a top surface of the metal layer; and filling the trench with a copper-containing material.

In some embodiments, a method of forming a semiconductor device may include forming a first structure, which may include forming a metal layer over a substrate; forming a barrier film over the metal layer, the barrier film having a dielectric constant of less than or about 5; forming a tetraethyl orthosilicate layer over the barrier film; forming a dielectric film over the tetraethyl orthosilicate layer, the dielectric film having a second dielectric constant greater than 7; etching a trench in the dielectric film, the tetraethyl orthosilicate layer, and the barrier film, where the trench may extend from a top surface of the dielectric film down to at least a top surface of the metal layer; forming a liner in the trench; and filling the trench with a copper-containing material.

In any embodiments, any and all of the following features may be implemented in any combination and without limitation. The semiconductor device may also include a second structure that includes a second metal layer overlaying a second substrate; a second dielectric layer overlaying the second metal layer and defining a second set of one or more features recessed in the second dielectric layer; a second dielectric film overlaying the second dielectric layer, the second dielectric film having a second dielectric constant greater than about 7; and a second copper-containing material deposited within the second set of one or more features, where the dielectric film of the first structure may be hybrid bonded to the second dielectric film of the second structure, wherein the copper-containing material of the first structure contacts the second copper-containing material of the second structure. The dielectric constant may be greater than about 8. The dielectric film may have a thickness of 5 nm. The dielectric film may include Al₂O₃. The copper-containing material may be characterized by a dish profile having a dish depth of less than or about 1 nm. Etching the trench in the dielectric film and dielectric layer may include etching the trench in the dielectric film with a chlorine-based etch. Etching the trench in the dielectric film and dielectric layer may include etching the trench in the dielectric film and dielectric layer with a multi-material etch, where the multi-material etch may include two or more of: a chlorine-based etch, a fluorine-based etch, an oxygen-plasma etch, and a fluorine-and-oxygen-based etch. Forming the metal layer and forming the dielectric layer may be performed in a first chamber, where etching the trench in the dielectric film and the dielectric layer may be performed in a second chamber, where the first structure may be moved from the first chamber to the second chamber without exposing the substrate to an external atmosphere. first structure may contact one or more slurries and one or more platens, where the one or more slurries and one or more platens may remove a portion of the copper-containing material and a second portion of the dielectric film. Contacting the first structure with the one or more slurries and one or more platens may recess the copper-containing material a distance of less than or about 1 nm within the trench below a top surface of the dielectric film. Contacting the first structure with the one or more slurries and one or more platens may cause the copper-containing material to be characterized by a dish profile. A liner may be formed in the trench, where filling the trench with the copper-containing material may include overlaying the liner with the copper-containing material. The method may also include contacting the first structure with a hydrogen-containing precursor; contacting the first structure with a second structure, the second structure that may include a second metal layer overlaying a second substrate, a second dielectric layer overlaying the second metal layer and defining a second set of one or more features in the second dielectric layer, a second dielectric film overlaying the second dielectric layer, the second dielectric film having a second dielectric constant greater than about 7; and a second copper-containing material deposited within the second set of one or more features; and bonding the first structure to the second structure, wherein the dielectric film of the first structure may be hybrid bonded to the second dielectric film of the second structure, wherein the copper-containing material of the first structure contacts the second copper-containing material of the second structure. Bonding the first structure to the second structure may include contacting the first structure with water; and annealing the first structure and the second structure. Bonding the first structure to the second structure may include contacting the first structure with water; and annealing the first structure and the second structure. The second dielectric constant may be greater than about 8, where the fourth dielectric constant may be greater than 8.

### BRIEF DESCRIPTION OF THE DRAWINGS

A further understanding of the nature and advantages of various embodiments may be realized by reference to the remaining portions of the specification and the drawings, wherein like reference numerals are used throughout the several drawings to refer to similar components.

In some instances, a sub-label is associated with a reference numeral to denote one of multiple similar components. When reference is made to a reference numeral without specification to an existing sub-label, it is intended to refer to all such multiple similar components.

FIG. 1 illustrates a top plan view of one embodiment of a processing system of deposition, etching, baking, and curing chambers that may be included or configured according to some embodiments.

FIG. 2 illustrates operations in a semiconductor processing method according to some embodiments.

FIG. 3A-3D illustrate exemplary schematic cross-sectional views of structures in which material layers are included and processed according to some embodiments.

FIG. 4 illustrates operations in a semiconductor processing method according to some embodiments.

FIGS. 5A-E illustrate exemplary schematic cross-sectional views of structures in which material layers are included and processed according to some embodiments.

### DETAILED DESCRIPTION

A structure for semiconductor devices having a high-dielectric constant dielectric film on the top surface of the structure can be used to form semiconductor devices that are composed of hybrid bonded structures with reduced dielectric surface area and reduced pitch for metal studs. For example, the dielectric constant of the dielectric film can be about or greater than 7 or 8. A semiconductor device can be formed by hybrid bonding the dielectric film of the structure to a dielectric film of a similar structure. A dielectric film-oxide-metal-substrate structure can be formed with the dielectric film on the top surface of the stack. A multi-material etch can be used etch features in the dielectric film and the oxide in a dielectric film-oxide-metal-substrate stack. A chemical-mechanical polishing technique can be used to precisely form the surface of the structure in preparation for hybrid bonding.

While conventional hybrid bonding systems may provide sufficient bond strength to bond two wafers under certain conditions, conventional systems may be limited to a pitch of a certain minimum size and/or a minimum percentage surface area of the dielectric on the surface of the wafers. Thus, the wafers are limited to a certain percentage of metal pads on the surface of the wafers and thus a limited metal density. For example, the pitch may have a minimum size of 1 micron and the dielectric bonding surface may be roughly 80% or more of the bonding surface between the wafers. The present technology overcomes these issues associated with conventional hybrid bonding systems by increasing bond strength between the dielectrics of dies. By forming a high-K dielectric layer on each die prior to the hybrid bonding of the wafers, the dielectric layers have stronger bond strength enabling a reduced pitch and a higher density of metal pads between the wafers.

As an overview, hybrid bonding is a semiconductor fabrication technique that combines the advantages of both direct bonding and traditional bonding methods. It enables the integration of dissimilar materials at a molecular level, facilitating the development of advanced semiconductor devices with improved performance, functionality, and miniaturization that may not require the use of metal interconnects. Hybrid bonding is particularly helpful for three-dimensional semiconductor device fabrication.

When a system consisting of two wafers (dies, substrates, and the like can also be used) are being bonded together via hybrid bonding, the dielectric layers of the wafers are first treated to create a reactive layer via surface activation. Then the dielectric layers can be contacted to each other to bond, for example by spontaneous hydrophilic oxide-oxide bonding. Once the dielectric layers have been bonded, the metal pads of each wafer will be separated by a dishing gap. The system can then be annealed such that the metal pads of each wafer will thermally expand and connect while the dielectric layers will remain approximately the same size by comparison to the metal. Once the annealing is complete, the wafers have been bonded via hybrid bonding.

Although the remaining disclosure will routinely identify specific hybrid bonding processes utilizing the disclosed technology, it will be readily understood that the systems and methods are equally applicable to a variety of other processes as may occur in the described chambers. Accordingly, the technology should not be considered to be so limited as for use with the described etching or deposition processes alone. The disclosure will discuss one possible system that can be used with the present technology before describing systems and methods or operations of exemplary process sequences according to some embodiments of the present technology. It is to be understood that the technology is not limited to the equipment described, and processes discussed may be performed in any number of processing chambers and systems.

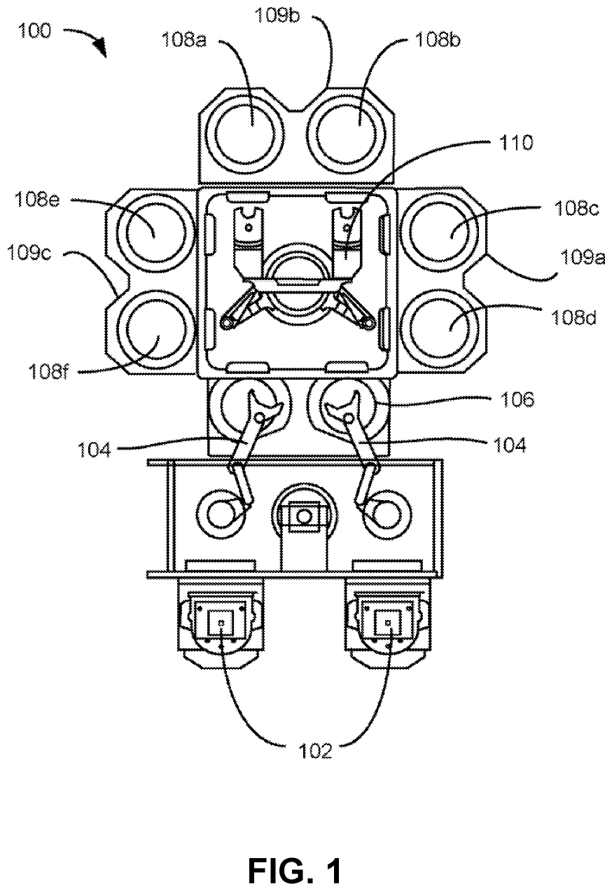

FIG. 1 illustrates a top plan view of one embodiment of a processing system 100 of deposition, etching, baking, and curing chambers that may be included or configured according to some embodiments of the present technology. In the figure, a pair of front opening unified pods 102 supply substrates of a variety of sizes that are received by robotic arms 104 and placed into a low pressure holding area 106 before being placed into one of the substrate processing chambers 108a-f, positioned in tandem sections 109a-c. A second robotic arm 110 may be used to transport the substrate wafers from the holding area 106 to the substrate processing chambers 108a-f and back. Each substrate processing chamber 108a-f can be outfitted to perform a number of substrate processing operations including the dry etch processes described herein in addition to cyclical layer deposition, atomic layer deposition, chemical vapor deposition, physical vapor deposition, etch, pre-clean, anneal, plasma processing, degas, orientation, and other substrate processes.

The substrate processing chambers 108a-f may include one or more system components for depositing, annealing, curing and/or etching a material film on the substrate or wafer. In one configuration, two pairs of the processing chambers, for example 108c-d and 108e-f, may be used to deposit material on the substrate, and the third pair of processing chambers, for example 108a-b, may be used to cure, anneal, or treat the deposited films. In another configuration, all three pairs of chambers, for example 108a-f, may be configured to both deposit and cure a film on the substrate. Any one or more of the processes described may be carried out in additional chambers separated from the fabrication system shown in different embodiments. It will be appreciated that additional configurations of deposition, etching, annealing, and curing chambers for material films are contemplated by system 100. Additionally, any number of other processing systems may be utilized with the present technology, which may incorporate chambers for performing any of the specific operations. In some embodiments, chamber systems which may provide access to multiple processing chambers while maintaining a vacuum environment in various sections, such as the noted holding and transfer areas, may allow operations to be performed in multiple chambers while maintaining a particular vacuum environment between discrete processes.

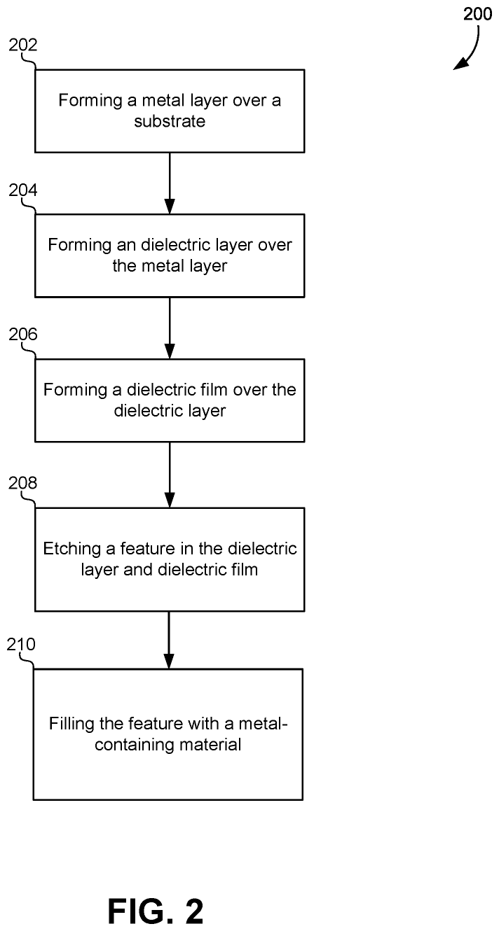

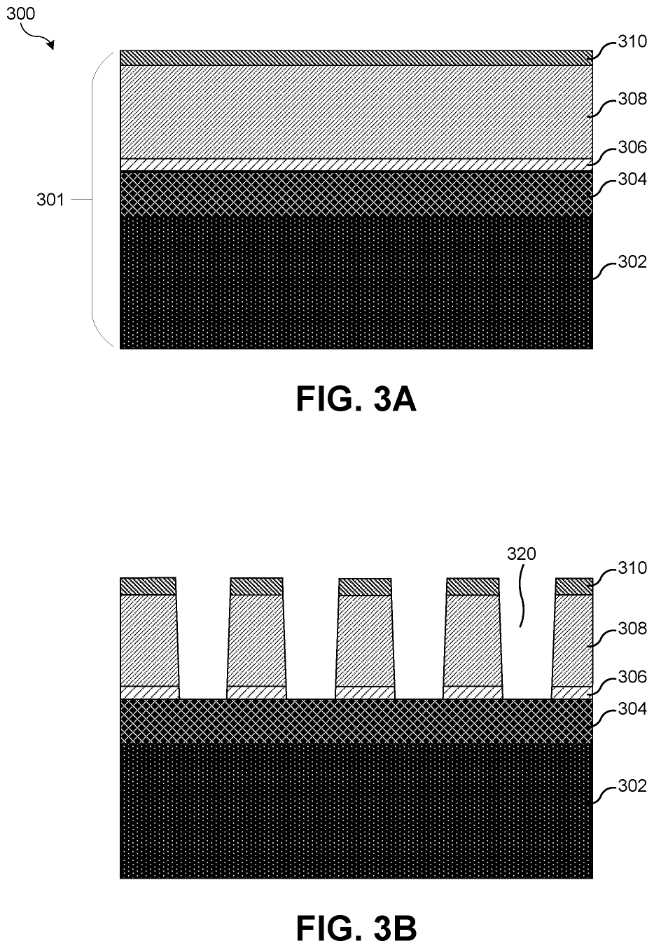

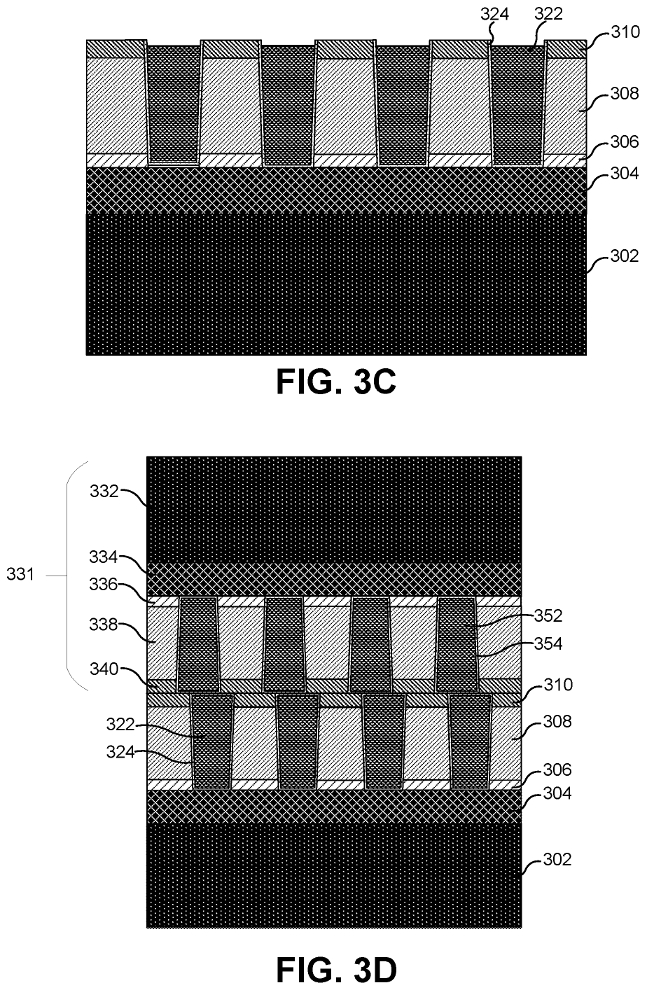

System 100, or more specifically chambers incorporated into system 100 or other processing systems, may be used to produce structures according to some embodiments of the present technology. FIG. 2 illustrates a flowchart of exemplary operations in a method 200 of forming a semiconductor device 300 for hybrid bonding that allows for a reduced pitch and stronger bond strength according to some embodiments of the present technology. The method 200 may be performed in a variety of processing chambers in which the operations may be performed, such as chambers incorporated in the system 100 described above. Method 200 may include one or more operations prior to the initiation of the method 200, including front-end processing, deposition, etching, polishing, cleaning, or any other operations that may be performed prior to the described operations. The methods 200 may include a number of optional operations, which may or may not be specifically associated with some embodiments of methods according to embodiments of the present technology. Method 200 may describe operations shown schematically in FIGS. 3A-3D, the illustrations of which will be described in conjunction with the operations of method 200. It is to be understood that the figures illustrate only partial schematic views, and a substrate 302 may contain any number of additional materials and features having a variety of characteristics and aspects as illustrated in the figures.

It should be appreciated that the specific steps illustrated in FIG. 2 provide particular methods of forming a semiconductor device 300 for hybrid bonding according to various embodiments. Other sequences of steps may also be performed according to alternative embodiments. For example, alternative embodiments may perform the steps outlined above in a different order. Moreover, the individual steps illustrated in FIG. 2 may include multiple sub-steps that may be performed in various sequences as appropriate to the individual step. Furthermore, additional steps may be added or removed depending on the particular applications. Many variations, modifications, and alternatives also fall within the scope of this disclosure.

FIGS. 3A-3D illustrate incremental structures for forming semiconductor device 300 for hybrid bonding, according to some embodiments. The method of flowchart 200 describes operations shown schematically in FIGS. 3A-3D, the illustrations of which will be described in conjunction with the operations of this method. It is to be understood that the figures illustrate only partial schematic views with limited details, and in some embodiments a substrate may contain any number of semiconductor sections having aspects as illustrated in the figures, as well as alternative structural aspects that may still benefit from any of the aspects of the present technology.

At operation 202, the method of flowchart 200 of forming a first structure 301 may include forming a metal layer 304 over a substrate 302. As illustrated in FIG. 3A, the structure 300 may include a substrate 302. The substrate 302 may have a substantially planar surface or an uneven surface in various embodiments. The substrate 302 may be a material such as crystalline silicon, silicon oxide, strained silicon, silicon germanium, doped or undoped polysilicon, doped or undoped silicon wafers, patterned or non-patterned wafers, silicon on insulator, carbon doped silicon oxides, silicon nitride, doped silicon, germanium, gallium arsenide, or sapphire. The substrate 426 may have various dimensions, such as 200 mm or 300 mm diameter wafers, as well as rectangular or square panels. The substrate 302 may be disposed within the processing region of the semiconductor processing chamber. Although shown as a planar substrate, it is to be understood that substrate 302 is included merely to represent an underlying structure, which may include any number of layers or features on a wafer or other substrate, and over which structures as described below may be formed.

As illustrated in FIG. 3A, the first structure 301 may include a metal layer 304. The metal layer 304 can include a variety of integrated circuits. For example, the integrated circuits can be created using technologies such as CMOS, NMOS, or any other suitable integrated circuit technology. As such, the metal layer 304 can include various layers of metal, oxide, and semiconductor. Metals used in the metal layer can include copper or any other high conductivity metal. Although this application will regularly discuss copper, it is to be understood that any number of conductive metal materials may be used in embodiments of the present technology, and the present technology should not be limited to any particular conductive metal material.

In some examples, the layers (for example, the substrate 302, the metal layer 304, and other layers described herein such as the barrier film 306, the second dielectric layer 308, and the dielectric film 310) described herein can be directly overlaying each other such that the first layer is overlaying the second layer. For example, the metal layer 304 can directly overlay the substrate 302 such that there are no intervening layers. In some examples, the layers described herein can have layers between them. For example, the metal layer 304 can be overlaying an intervening layer which overlays the substrate 302. Furthermore, when forming a layer, any process for forming or depositing material can be used. For example, chemical vapor deposition (CVD) can be used in some examples while atomic layer deposition (ALD) can be used in other examples. Specifics regarding specific layers and/or materials are also described herein.

At operation 204, the method of flowchart 200 of forming the first structure 301 may include forming a dielectric layer 308 over the metal layer 304. As illustrated in FIG. 3A, the dielectric layer 308 may include one or more layers of dielectrics. Example dielectrics can include silicon oxide, tetraethyl orthosilicate (also referred to as TEOS or TeOs), or any other kind of oxide. The dielectric layer 308 can also be referred to as the oxide layer.

In some examples, the first structure 301 can include a barrier film 306 between the dielectric layer 308 and the metal layer 304. A barrier film 306 can have a low dielectric constant in order to reduce the dielectric constant of copper damascene structures in order to achieve faster and more powerful devices. Some barrier films can have a dielectric constant of less than 5 or even lower. Example barrier films include silicon nitride films, and low-k barrier films such as BLoK (a Si—C—H compound) or N-BLoK (a Si—C—H—N compound) developed by Applied Materials. The barrier film 306 can also be referred to as a capping layer for metal layers. Although the following description will regularly discuss a dielectric layer, it is to be understood that any number of dielectric materials and/or layers of dielectric materials may be used in embodiments of the present technology, and the present technology should not be limited to any particular dielectric material.

At operation 206, the method of flowchart 200 of forming the first structure 301 may include forming a dielectric film 310 over the dielectric layer 308. As illustrated in FIG. 3A, the structure 300 may include a dielectric film 310. In some examples, the dielectric film 310 can be a dielectric material with a dielectric constant K of about 7 or greater. Example of a dielectric film with sufficiently high dielectric constant K of 7 can be silicon nitride (Si₃N₄). In some examples, the dielectric film 310 can be a dielectric material with a dielectric constant K of about 8 or greater. In some examples, the dielectric film 310 can be a dielectric constant K of about 9 or greater. Examples of dielectric films with a sufficiently high dielectric constant K of 9 or greater include aluminum oxide (Al₂O₃), titanium oxide (TiO₂), Strontium titanate (SrTiO₃), zirconium oxide (ZrO₂), Hafnium oxide (also referred to as Hafnium (IV) oxide, HfO₂), Hafnium silicate (also referred to as Hafnium (IV) silicate, HfSiO₄), lanthanum oxide (La₂O₃), Yttrium oxide (also referred to as Yttrium (III) oxide, Y₂O₃), and lanthium aluminate (LaAlO₃). These materials may need a special end-line processing and/or special etches due to the chemical properties of these materials as compared to more conventional materials such as silicon oxide. In some examples, the dielectric film 310 can be a dielectric constant K of about 10 or greater. In some examples, the dielectric film 310 can be a dielectric constant K of about 11 or greater.

In some examples, forming the dielectric film 310 can be done in a different chamber of the system 100 than forming the dielectric layer 308. In some examples, the formation of each layer can be done in different chambers. In some examples, the formation of the dielectric layer 308, the barrier film 306, the metal layer 304, and/or substrate 302 can be done in a single chamber.

In some examples, forming the dielectric film 310 can include depositing the dielectric material via atomic layer deposition. Depositing the dielectric material may include contacting the first structure 301 with a hydrogen-containing precursor. The first structure 301 can be contacted by a hydrogen-containing precursor in order to hydroxylate the surface of the dielectric layer 308. Hydroxylating the surface of the dielectric layer 308 can form a surface activation layer on the dielectric layer 308 such that hydrogen atoms form off the lattice of the dielectric layer 308. The hydrogen-containing precursor can be contacted with the first structure via any suitable means, for example CVD plasma-enhanced CVD, ALD, and the like.

Once the surface of the dielectric layer 308 has been activated to form a surface activation layer, precursors can be applied to the first structure 301 to form the dielectric film 310. In some examples, the structure 301 can be contacted by one or more precursors. The precursors can react with the surface of the surface activation layer of the dielectric layer 308 depositing an atomic layer of a material, for example, a dielectric. As in a conventional ALD process, the first structure 301 can be contacted by first precursor and then a second precursor (or any number of precursors), alternating contact between the first precursor and the second precursor (or any number of precursors), to deposit atomic layers of a dielectric material to form a dielectric film 310. The one or more precursors 718 can be selected to produce a specific dielectric film 310 on the surface of the dielectric layer 308. For example, the ALD process for depositing aluminum oxide can alternate precursors of trimethylaluminium and water. Any suitable combinations of precursors can be used.

In embodiments, there may be a determination of whether a target thickness of the dielectric film 310 has been achieved following operation 206. If a target thickness of the dielectric film 310 has not been achieved, another cycle of ALD can be performed. Exemplary ranges of target thickness to discontinue further cycles of forming dielectric film 710 include less than or about 10 nm. Additional exemplary thickness ranges may include less than or about 9.5 nm, less than or about 9.0 nm, less than or about 8.5 nm, less than or about 8.0 nm, less than or about 7.5 nm, less than or about 7.0 nm, less than or about 6.5 nm, less than or about 6.0 nm, less than or about 5.5 nm, less than or about 5.0 nm, less than or about 4.5 nm, less than or about 4.0 nm, less than or about 3.5 nm, less than or about 3.0 nm, less than or about 2.5 nm, less than or about 2.0 nm, less than or about 1.5 nm, less than or about 1.0 nm, less than or about 0.5 nm, or less, including any fraction of any of the stated numbers.

At operation 208, the method of flowchart 200 of forming the first structure 301 may include etching a feature in the dielectric layer 308, the dielectric film 310, and the barrier film 306 if applicable. Features etched into the dielectric layer 308 and dielectric film 310 can include trenches, apertures or vias, or any other structure useful in semiconductor processing. As illustrated in FIG. 3B, the structure 300 may include a trench 320 in the dielectric film 310 and the dielectric layer 308. In some examples, the trench 320 can extend from a top surface of the dielectric film 310 down to at least a top surface of the metal layer 304. Although only four features are shown in the figure, it is to be understood that exemplary structures may have any number of features defined along the structure according to embodiments of the present technology.

The etchant used to etch the features into the dielectric layer 308, dielectric film 310, and if applicable the barrier film 306 can include a variety of semiconductor processing etches that are either solutions or plasmas, such as chlorine, fluorine, oxygen plasma, or fluorine-and-oxygen. In some examples, the etchants can be applied one at a time. In some examples, multiple etchants can be combined to form a multi-material etch. An etchant for the dielectric film 310 can be different than an etchant for the dielectric layer 308 or parts of the dielectric layer 308. In some examples, a chlorine etch can be used on a dielectric film 310 of the material aluminum oxide. In some examples, a fluorine etch can be used on a TEOS layer of the dielectric layer 308.

In some examples, an ashing etch such as an oxygen plasma can be used to remove organics. In some examples, a fluorine-and-oxygen etch can be used on a BLoK or n-BLoK layer of the barrier film 306. In some examples, one or more etches can be dry reactive ion etches. In some examples, one or more etches can be wet etches. Different etchants can have selectivity for different layers such that when an etchant is used it will primarily etch a targeted layer rather than other layers exposed to the etch. For example, a fluorine etch used on a TEOS layer of the dielectric layer 308 may selectively etch the TEOS layer rather than the dielectric film 310. The selectivity of the etch can make the etching of the targeted layer at a rate that is greater than or about 1.5:1 compared to one or more other layers, and may be greater than or about 1.6:1, greater than or about 1.7:1, greater than or about 1.8:1, greater than or about 1.9:1, greater than or about 2.0:1, greater than or about 2.1:1, greater than or about 2.2:1, greater than or about 2.3:1, greater than or about 2.4:1, greater than or about 2.5:1, greater than or about 2.6:1, greater than or about 2.7:1, greater than or about 2.8:1, greater than or about 2.9:1, greater than or about 3.0:1, or more.

At operation 210, the method of flowchart 200 of forming the first structure 301 may include filling the feature with a metal-containing material. As illustrated in FIG. 3C, the structure 300 may include a metal-containing material 322 in the trench 320. The metal-containing material 322 can be a high conductivity material that can be used as an interconnect between integrated circuits. In some examples, the metal in the metal-containing material 322 includes copper such that the metal-containing material 322 is a copper-containing material. Metals used to fill the feature can include copper or any other high conductivity metal. Although this application will regularly discuss copper, it is to be understood that any number of conductive metal materials may be used in embodiments of the present technology, and the present technology should not be limited to any particular conductive metal material.

In some examples, a liner is formed in the trench prior to filling the trench with the metal-containing material. As illustrated in FIG. 3C, the structure 300 may include a liner 324 in the trench 320 such that the liner lies in the trench 320 between the dielectric layer 308 and the metal-containing material 322. In some embodiments, the liner 324 may be tantalum nitride, or any other suitable liner material incorporated to limit or prevent the potential for diffusion of metal into the dielectric material.

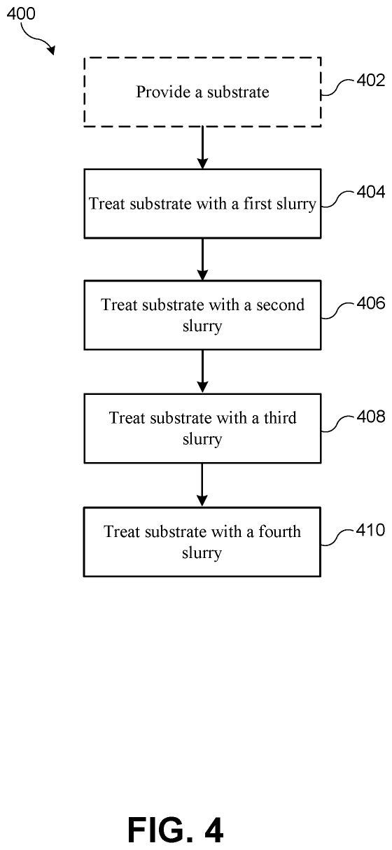

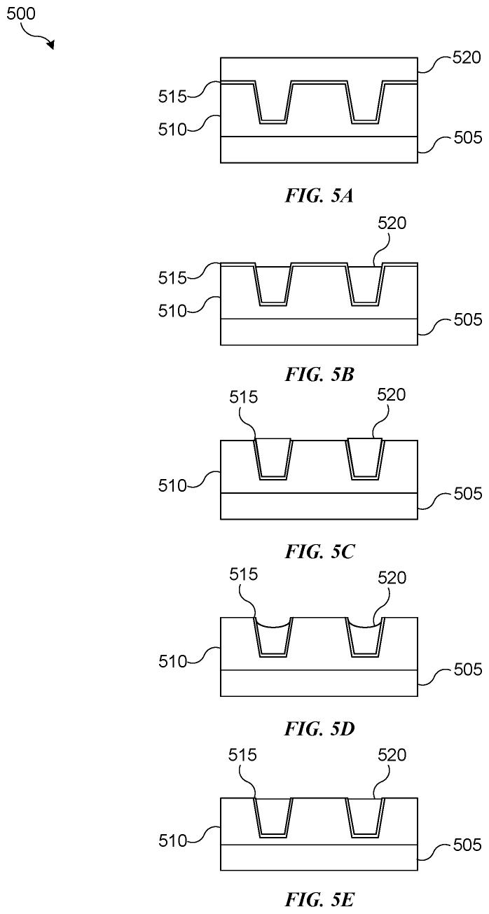

In some examples, after the feature has been filled with a metal-containing material 322, the first structure 301 can be polished via a chemical-mechanical polishing (CMP) process as described herein with greater detail in relation to FIGS. 4 and 5A-5E and as described in U.S. patent application Ser. No. 17/411,599, which is incorporated by reference herein in its entirety. After the first structure 301 has been polished via the CMP process, the top surface of the metal-containing material 322 can be recessed in relation to the top surface of the dielectric film 310, for example as illustrated in FIG. 3C. The CMP process may cause the top surface of the metal-containing material 322 to form a concave shape or dish shape that may feature a nadir or dish depth, respectively, that is the difference in height between the lowest point in the metal and the surface from which the feature is formed in the dielectric material, or a difference in edge height of the metal within the feature. If the nadir or dish depth combined with a recession depth of the top surface of the metal-containing material 322 to the top surface of the dielectric film 310 (the combination being referred to as combined depth) is too great, the material may not be useful for certain end products. For example, copper-to-copper hybrid bonding is one such application that may be sensitive to an imprecise combined depth. In some applications of copper-to-copper hybrid bonding, if the combined depth is too great, the copper-to-copper bond may not be sufficiently strong due to limited contact with studs from mating features, or the coupling may not occur at all. A combined depth of less than 5 nm may be small enough for copper-to-copper hybrid bonding, for example.

In some examples, the liner 324 can be polished via the CMP process such that the top surface of the liner 324 aligns with the top surface of the dielectric layer 308. In some examples, the liner 324 can be polished via the CMP process such that the top surface of the liner 324 aligns with the top surface of the metal-containing material 322 as seen in FIG. 3C. In some examples, the liner 324 can be polished via the CMP process such that the top surface of the liner 324 is recessed in relation to the top surface of the dielectric layer 308 and protruding in relation to the top surface of the metal-containing material 322.

In some examples, the method of flowchart 200 may further include bonding the first structure 301 to a second structure 331 via hybrid bonding as shown in FIG. 3E. In some examples, the second structure 331 is similar to the first structure 301 in layout, layers, and materials used. The second structure 331 can include a second metal layer 334 overlaying a second substrate 332. The second metal layer 334 can be similar to the metal layer 304 such that all description of the metal layer 304 is applicable to the second metal layer 334. The second substrate 332 can be similar to the substrate 302 such that all description of the substrate 302 is applicable to the second substrate 332. The second structure 331 can also include a second dielectric layer 338 overlaying the second metal layer 334 and defining a second set of one or more features in the second dielectric layer 338. The second dielectric layer 338 of the second structure 331 can be similar to the dielectric layer 308 of the first structure 301 such that all description of the dielectric layer 308 is applicable to the second dielectric layer 338. In some examples, the second structure 331 can include a second barrier film 336 between the second dielectric layer 338 and the second metal layer 334. The second barrier film 336 can be similar to the barrier film 306 such that all description of the barrier film 306 is applicable to the second barrier film 336. The second structure 331 can include a second dielectric film 340 overlaying the second dielectric layer 338. The second dielectric film 340 can be similar to the dielectric film 310 such that all description of the dielectric film 310 is applicable to the second dielectric film 340. In some examples, the material used for the dielectric film 310 is the same material used for the second dielectric film 340. The second structure 331 can include a second metal-containing material 354 deposited within the second set of one or more features. The second metal-containing material 354 can be similar to the metal-containing material 322 such that all description of the metal-containing material 322 is applicable to the second metal-containing material 354. In some examples, the material used for the metal-containing material 322 is the same material used for the second metal-containing material 354. In some examples, the second dielectric film 340 does not overlay the second metal-containing material 354. In some examples, the second structure 331 may include a second liner 354 in the second set of one or more features such that the second liner 354 lies between the second set of one or more features in the second dielectric layer 338 and the second metal-containing material 354. The second liner 354 can be similar to the liner 324 such that all description of the liner 324 is applicable to the second liner 354. In some examples, the first structure 301 can be considered to be hybrid-bonded to the second structure 331. In some examples, the dielectric film 310 can be considered hybrid-bonded to the second dielectric film 430. In some examples, the metal-containing material 322 can be considered hybrid-bonded to the second metal-containing material 354.

In some examples, bonding the first structure 301 to the second structure 331 can include using a surface activation process on the first structure 301 and/or the second structure 331. The surface activation process can include contacting the first structure 301 and/or the second structure 331 with a hydrogen-containing precursor. The surface activation process can activate the top surface of the dielectric film 310 of the first structure 301 and/or the top surface of the second dielectric film 340 of the second structure 331 such that either one or both surfaces have been hydroxylated to have dangling hydroxylation groups. In some examples, water is then applied to the top surface of the dielectric film 310 of the first structure 301 and/or the top surface of the second dielectric film 340 of the second structure 331.

The top surface of the dielectric film 310 of the first structure 301 and the top surface of the second dielectric film 340 of the second structure 331 can then be aligned and contacted. When the top surface of the dielectric film 310 contacts the top surface of the second dielectric film 340, a spontaneous bonding occurs primarily via Van der Waals bonds to set an initial bond between the top surface of the dielectric film 310 and the top surface of the second dielectric film 340. This causes the first structure 301 and the second structure 331 to be bonded together via the top surface of the dielectric film 310 contacting the top surface of the second dielectric film 340. The initial bond between the first structure 301 and the second structure 331 may not be the finalized bond but can be used to keep the first structure 301 and the second structure 331 aligned as additional processes are run to finalize the hybrid bond.

The combination structure of the first structure 301 and the second structure 331 can then annealed. During the annealing operation, the dielectric film 310 and the second dielectric film 340 may further form oxide-to-oxide covalent bonds increasing the bond strength between the dielectric film 310 and the second dielectric film 340. In some examples, the water and/or the dangling hydroxylation groups assist in forming the oxide-to-oxide covalent bonds between the dielectric film 310 and the second dielectric film 340. Because the dielectric constants of the dielectric film 310 and the second dielectric film 340 are high (for example, a dielectric constant of 7 or greater, or 9 or greater as described herein), the covalent bonds between the top surface of the dielectric film 310 and the top surface of the second dielectric film 340 are quite strong. The strength of the covalent bonds enables the surface area of the dielectric film 310 and the second dielectric film 340 to be a lower ratio than traditional hybrid bonding techniques. Once the oxide-to-oxide covalent bonds between the dielectric film 310 and the second dielectric film 340 form, the bond between the dielectric film 310 and the second dielectric film 340 can be indistinguishable from the bonds within the dielectric film 310 and/or the second dielectric film 340. Because the dielectric film 310 and the second dielectric film 340 have high dielectric constants (for example, greater than 7 or greater than 9 as described herein), the bond strength between the dielectric film 310 and the second dielectric film 340 can be twice as strong or more when compared to bond strength between conventional dielectric layers being hybrid bonded together. For example, the bond strength between a dielectric film 310 of aluminum oxide and a second dielectric film 340 of aluminum oxide can be twice as strong or more when compared to bond strength between conventional dielectric layers (such as silicon oxide) being hybrid bonded together.

The annealing of the combination structure can also cause the metal-containing material 322 to extrude towards the second metal-containing material 354. As previously described, the combined depth of the metal-containing material 322 (and the second metal-containing material 354 by extension) is important for the bonding of the metal-containing materials. When the combined depth is less than 5 nm or lower, subsequent annealing to bond the metal-containing material 322 and the second metal-containing material 354 may be effective as the metal-containing material 322 and the second metal-containing material 354 may be close enough to bond to each other during the annealing step of hybrid bonding. During the annealing step, the metal-containing materials from the two structures may extrude towards one another, may contact each other, and may bond. At reduced annealing temperatures according to some embodiments of the present technology, unless the dishing is sufficiently reduced, the amount of expansion may be insufficient to allow adequate coupling between the copper. By performing polishing operations according to the present technology, reduce dishing may be provided, which may improve coupling capability between substrates at reduced annealing temperatures.

Once the annealing process is completed, the first structure 301 and the second structure 331 are hybrid bonded to form a single semiconductor device or a single structure. The use of hybrid bonding enables the fabrication of complex semiconductor devices from multiple structures and form the interconnects between the structures.

FIG. 4 illustrates a flowchart of exemplary operations in a chemical-mechanical polishing processing method 400 according to some embodiments of the present technology. The method 400 may be performed in a variety of processing chambers, including a polishing system, as well as any other chambers such as chambers incorporated in the system 100 described above. Method 400 may include one or more operations prior to the initiation of the method 400, including front-end processing, deposition, etching, polishing, cleaning, or any other operations that may be performed prior to the described operations. The methods 400 may include a number of optional operations, which may or may not be specifically associated with some embodiments of methods according to embodiments of the present technology. Method 400 may describe operations shown schematically in FIGS. 5A-5E, the illustrations of which will be described in conjunction with the operations of method 400. It is to be understood that the figures illustrate only partial schematic views, and a substrate 505 may contain any number of additional materials and features having a variety of characteristics and aspects as illustrated in the figures.

It should be appreciated that the specific steps illustrated in FIG. 4 provide particular methods of chemical-mechanical polishing according to various embodiments. Other sequences of steps may also be performed according to alternative embodiments. For example, alternative embodiments may perform the steps outlined above in a different order. Moreover, the individual steps illustrated in FIG. 4 may include multiple sub-steps that may be performed in various sequences as appropriate to the individual step. Furthermore, additional steps may be added or removed depending on the particular applications. Many variations, modifications, and alternatives also fall within the scope of this disclosure.

Method 400 may or may not involve optional operations to develop the semiconductor structure to a particular polishing operation, such as one or more semiconductor processing operations to develop one or more layers of material on a substrate and clamping a substrate to a carrier head of a polishing system. It is to be understood that method 400 may be performed on any number of semiconductor structures or substrates 505 (for example, the substrate 302, the dielectric layer 308, and/or metal layer 304 of FIG. 3A), as illustrated in FIG. 5A, including exemplary structure 500 (for example, the first structure 301 of FIG. 3A) on which dielectric film 510 (for example, the dielectric film 310 of FIG. 3A), liner 515 (for example, the liner 324 of FIG. 3C), and copper-containing layer 520 (for example, the metal-containing layer 322 of FIG. 3C) may be formed. Although the following description will regularly discuss the dielectric film 510, it is to be understood that the following description can also be applied to any dielectric of the dielectric layer 308 described in relation to FIG. 3A, such that the present technology should not be limited to any particular dielectric material in which features may be formed. Although the following description will regularly discuss a copper-containing layer, it is to be understood that any number of metal-containing materials may be used in embodiments of the present technology, and the present technology should not be limited to any particular metal-containing material in which features may be formed. As illustrated in FIG. 5A and described in relation to FIG. 3B, the dielectric film 510 may be processed to form one or more recesses or features, such as trenches, apertures or vias, or any other structure useful in semiconductor processing. Substrate 505 may be any number of materials, such as a base wafer or substrate 505 made of silicon or silicon-containing materials, or other substrate materials. For example, in some embodiments the substrate may be processed to include one or more materials or structures for semiconductor processing, such as the dielectric film 510, liner 515, and copper-containing layer 520. Although only two features are shown in the figure, it is to be understood that exemplary structures may have any number of features defined along the structure according to embodiments of the present technology.

In some embodiments, method 400 may include providing a substrate 505 at optional operation 402 to a polishing assembly, such as the substrate 505 depicted in FIG. 5A. The substrate 505 may include the dielectric film 510 defining one or more features recessed from a surface of the dielectric film 510, a liner 515 extending across the dielectric film 510 and a dielectric layer (for example, the dielectric layer 308) and within the one or more features, and a copper-containing layer 520 deposited on the liner 515 and extending within the one or more features. In some embodiments, the liner 515 may be tantalum nitride, or any other suitable liner material incorporated to limit or prevent the potential for diffusion of metal into the dielectric film, dielectric layer, or other dielectric materials. As previously described, the dielectric film 510, liner 515, and copper-containing layer 520 may be formed by any number of processing techniques that may be performed to develop a substrate and produce the structure described.

As will be described in greater detail below, during the polishing in method 400, the overall removal rate of metal, such as the copper-containing layer 520, may be greater than the removal rate of dielectric material, such as the dielectric film 510, when utilizing the metal-selective slurry. Additionally, the dielectric-selective slurry may still cause an amount of removal of the metal, when exposed to the polishing pad and slurry. Further, the rate of removal in the copper-containing layer 520 may be greater towards the center of the copper in the one or more features as this copper may be a softer, bulk material. This greater rate of removal may result in a concave shape or dish shape forming in the copper during polishing. As previously explained, too much dishing may be considered a defect in polishing processing for copper-to-copper hybrid bonding applications. The concave shape or dish shape may feature a nadir or dish depth, respectively, that is the difference in height between the lowest point in the metal and the surface from which the feature is formed in the dielectric material, or a difference in edge height of the metal within the feature. If the nadir or dish depth is too great, the material may not be useful for certain end products. For example, copper-to-copper hybrid bonding is one such application that may be sensitive to an imprecise nadir or dish depth. In some applications of copper-to-copper hybrid bonding, if the nadir or dish depth is too great, the copper-to-copper bond may not be sufficiently strong due to limited contact with studs from mating features, or the coupling may not occur at all. In these applications substrate 505 having copper-containing layers 520 may be contacted by a secondary substrate for mating during back end of line process, and prior to an annealing operation. The dielectric material of each substrate 505, such as the dielectric film 510, may contact the dielectric material of the other substrate such that the two separate substrates may bond into one structure. During the annealing operation, the dielectric materials may form oxide-to-oxide covalent bonds. The copper-containing layer 520 of the mating substrate may also extrude to contact the copper-containing layer 520 of the substrate 505. If the nadir or dish depth is too great, the copper-containing layer 520 may be too far recessed to connect with the copper stud during the annealing operation to contact the other copper-containing layer.

After providing the substrate 505 to the polishing assembly, the substrate 505 may be contacted with a first slurry at operation 404. As used throughout the disclosure, contact may be used interchangeably with polish, as contacting the substrate 505 with a slurry may result in a chemical operation that polishes the substrate 505. In some embodiments, at operation 404, the method 400 may include contacting the substrate 505 with a first platen in addition to the first slurry. Contacting the substrate 505 with the first slurry, and the first platen in some embodiments, may remove a first portion of the copper-containing layer 520. Operation 404 may remove the first portion of the copper-containing layer 520 such that the copper-containing layer 520 may be recessed below the liner 515, which may fully separate the regions of copper across the substrate 505 and ensure the metal does not connect discrete regions of copper across the substrate. Removing the first portion of the copper-containing layer 520 may isolate individual copper plugs within the copper-containing layer 520. The copper plugs may refer to the portions of the copper-containing layer 520 that extend into the one or more features. The first slurry may be selective to copper and removing the copper-containing layer 520 may not remove a substantial amount of the liner 515. Therefore, operation 404 may remove the copper-containing layer 520 such that the liner 515 may be at least partially exposed and that the copper-containing layer 520 may be recessed to expose the liner 515 across a surface of the substrate and/or in the one or more features of the dielectric film 510, as shown in FIG. 5B.

At operation 406, the substrate 505 may be contacted with a second slurry. In some embodiments, at operation 406, the method 400 may include contacting the substrate 505 with a second platen in addition to the second slurry. The second slurry, and the second platen in some embodiments, may remove at least a portion of the liner 515 and/or a first portion of the dielectric film 510. The second slurry may be selective to removing the liner 515 and may not remove a substantial amount of the copper-containing layer 520. The second slurry may be selective to oxide and nitride materials, and may remove the liner and/or the oxide material at a rate that is greater than or about 1.5:1 compared to copper, and may be greater than or about 1.6:1, greater than or about 1.7:1, greater than or about 1.8:1, greater than or about 1.9:1, greater than or about 2.0:1, greater than or about 2.1:1, greater than or about 2.2:1, greater than or about 2.3:1, greater than or about 2.4:1, greater than or about 2.5:1, greater than or about 2.6:1, greater than or about 2.7:1, greater than or about 2.8:1, greater than or about 2.9:1, greater than or about 3.0:1, or more. The second slurry may remove the portion of the liner 515 that may be exposed after operation 404. That is, the portion of the liner 515 between the dielectric film 510 and the first portion of the copper-containing layer 520, such as the portion of the copper-containing layer 520 that was removed in operation 404, may be removed during operation 406. As the portion of the liner 515 may be removed, the copper-containing layer 520 may protrude above the dielectric film 510 based on the selectivity of removal, as shown in FIG. 5C.

After the substrate 505 is contacted with the second slurry, the substrate 505 may be contacted with a third slurry at operation 408. In some embodiments, at operation 408, the method 400 may include contacting the substrate 505 with a third platen in addition to the third slurry. The third slurry, and the third platen in some embodiments, may remove at least a second portion of the copper-containing layer 520. The third slurry may be selective to removing the copper-containing layer 520 and may not remove a substantial amount of the dielectric film 510. In some examples, the third slurry may remove the second portion of the copper-containing layer 520 that may be exposed after operation 404 and operation 406. That is, the copper-containing layer 520 protruding above dielectric film 510 may be removed during operation 408 such that the copper-containing layer 520 may be recessed below the dielectric film 510, as shown in FIG. 5D. Operation 408 may be performed at a higher pressure than operation 404 or operation 406. This higher pressure may result in faster removal of softer, bulk copper in the middle of the one or more features of the substrate 505. This faster removal may result in dishing occurring in the copper-containing layer 520 as illustrated. In some embodiments, the third slurry may be the same as the first slurry. Additionally or alternatively, the third platen may be the same as the first platen.

During contacting of the substrate 505 with the third slurry, the copper-containing material 520 may be purposefully recessed below the dielectric film 510. Purposefully recessing, or dishing, the copper-containing material 520 below suitable levels for copper-to-copper hybrid bonding may allow for a longer duration of operation 410, which may be preferred such that greater control may be exerted over the duration of operation 410. For example, if the copper-containing material 520 is only slightly recessed below the dielectric film 510, the duration of operation 410 may be so short that greater dishing of the copper-containing material 520 than desirable may inadvertently occur, which may cause uniformity issues, or over etching of the materials. If the copper containing material 520 is over-recessed below the dielectric film 510, operation 410 may take longer and may be a slower process, which may allow the final nadir or dish depth to be controlled to a finer degree.

After operation 408, the copper-containing layer 520 may be characterized by a concave profile within the one or more features in the dielectric film 510. The copper-containing layer 520 may additionally or alternatively be characterized by a dish profile having a dish depth. A nadir of the concave profile, or a dish depth of the dish profile, after operation 408 may be greater than or about 5 nm within a surface of the dielectric film 510, and may be greater than or about 6 nm, greater than or about 7 nm, greater than or about 8 nm, greater than or about 9 nm, greater than or about 10 nm, greater than or about 6 nm, greater than or about 11 nm, greater than or about 12 nm, greater than or about 13 nm, greater than or about 14 nm, greater than or about 15 nm, or higher.

A nadir or dish depth of greater than 5 nm may be too large for copper-to-copper hybrid bonding, for example. When the nadir or dish depth is greater than or about 5 nm or higher, subsequent annealing to bond the separate copper elements may not be effective as the copper may be too far apart. During annealing, the separate copper elements may extrude towards each other, but if the nadir or dish depth is too greater, the copper elements will not bond to each other. If the nadir or dish depth is too little, such that the copper protrudes from one or both of the substrates 505, the dielectric materials of the substrates 505 will not be able to bond to one another sufficiently. Further, temperature during annealing may be limited by other components on the substrate 505, such as gallium nitride, which may have a thermal limit of about 400° C. This thermal limit may prevent the annealing from occurring at a much higher temperature than of about 400° C. By performing the coupling at lower temperatures, the amount of thermal expansion may also be reduced, which may further limit copper expansion and coupling between the copper materials. Therefore, additional processing to fine-tune the nadir or dish depth of the copper-containing layer 520 may be necessary such that a copper-to-copper bond may form when separate copper elements of two substrates 505 are contacted.

At operation 410, the substrate 505 may be contacted with a fourth slurry. In some embodiments, at operation 410, the method 400 may include contacting the substrate 505 with a fourth platen in addition to the fourth slurry. The fourth slurry, and the fourth platen in some embodiments, may remove at least a second portion of the dielectric film 510. In some embodiments, the fourth slurry may be selective to removing the dielectric film 510 and may not remove a substantial amount of the copper-containing layer 520. Contacting the substrate 505 with the fourth slurry and the fourth platen may further remove a third portion of the copper-containing layer 520. At operation 410, the copper-containing material 520 may be recessed such that the fourth slurry and the fourth platen may not immediately remove the copper-containing material 520. Instead, the fourth slurry and the fourth platen may remove only the dielectric film 510 until the dielectric film 510 is removed to a level near the copper-containing material 520. Once the dielectric film 510 is removed to a level near the copper-containing material 520, the fourth slurry and the fourth platen may also remove the copper-containing material 520. The fourth slurry and the fourth platen may begin removing the copper-containing material 520 when the dielectric film 510 is less than or about 2 nm higher than the copper-containing material 520, such as less than or about 1 nm. The fourth slurry may remove the dielectric film 510 that may be extending above the copper-containing layer 520 after operation 408. That is, the dielectric film 510 above copper-containing layer 520 may be removed during operation 410 such that the copper-containing layer 520 may be recessed below the dielectric film 510 in a lesser amount than in operation 408, as shown in FIG. 5E. In some embodiments, the fourth slurry may be the same as the second slurry. Additionally or alternatively, the fourth platen may be the same as the second platen.

Contacting the substrate 505 with the fourth slurry, and in some embodiments the fourth platen, may continue for a period of time of greater than or about 10 seconds. When the period of time is greater than or about 10 seconds, this may allow processing to be finely tuned to remove a desirable amount of dielectric film 510 such that the remaining nadir of the concave profile or dish depth of the dish profile of the copper-containing layer 520 may be precise. A precise nadir of the concave profile or dish depth of the dish profile, as further described below, may be necessary for further processing and applications of the semiconductor substrate.

In some embodiments, the method 400 may include diluting the second slurry to form the fourth slurry. Diluting the second slurry to form the fourth slurry may control the rate at which dielectric film 510 is removed when the substrate 505 is contacted with the fourth slurry. The fourth slurry may be diluted previous to operation 410 or, alternatively, on-platen during operation 410. The fourth slurry may be characterized by a slurry concentration of less than or about 50% of the second slurry, and may be characterized by a slurry concentration of less than or about 47% of the second slurry, less than or about 45% of the second slurry, less than or about 43% of the second slurry, less than or about 40% of the second slurry, less than or about 37% of the second slurry, less than or about 35% of the second slurry, less than or about 33% of the second slurry, or lower. Similar to the removal selectivity between dielectric film 510 and copper discussed above, the fourth slurry being a dilute version of the second slurry may provide that the fourth slurry removes dielectric film 510 and copper-containing layer 520 at a rate such that the nadir of the concave profile or dish depth of the dish profile of the copper-containing layer 520 may be precise enough for subsequent copper-to-copper hybrid bonding.

Diluting the fourth slurry may reduce a removal selectivity between dielectric film 510 and copper. Diluting the fourth slurry may reduce a removal selectivity between dielectric film 510 and copper of less than or about 2:1, and may produce a removal selectivity between dielectric film 510 and copper of less than or about 1.9:1, less than or about 1.8:1, less than or about 1.7:1, less than or about 1.6:1, less than or about 1.5:1, less than or about 1.4:1, less than or about 1.3:1, less than or about 1.2:1, less than or about 1.1:1, less than or about 1.1:1, or lower. A removal selectivity between dielectric film 510 and copper of less than or about 2:1 may provide that the fourth slurry removes dielectric film 510 and copper-containing layer 520 at a sufficiently slow rate such that the removal operation may reduce the dishing of the copper by slowly removing the oxide and edge metal material. As shown in FIG. 4, the more dilute the fourth slurry is, the lower the removal selectivity may be. A removal selectivity between dielectric film 510 and copper of less than or about 2:1 may provide that the fourth slurry removes dielectric film 510 and copper-containing layer 520 at a rate such that the nadir of the concave profile or dish depth of the dish profile of the copper-containing layer 520 may be precise enough for subsequent copper-to-copper hybrid bonding.

Referring again to FIG. 4, during operation 410, contacting the substrate 505 with the fourth slurry may etch, or remove, dielectric film 510 at an etch rate of less than or about 15 nm per minute. The etch rate may provide that the fourth slurry removes dielectric film 510 at a rate slow enough to control the final nadir or dish depth of the copper-containing layer 520 such that the structure can be used in a variety of applications, such as copper-to-copper hybrid bonding. By slowing the removal of the dielectric film 510, the removal of the copper-containing layer 520 may also be slowed. Slowing the removal of the copper-containing layer 520 may aid in reducing the nadir or dish depth in the copper-containing layer 520, such that the material may be used in copper-to-copper hybrid bonding. The etch rate may be less than or about 15 nm per minute, and may be less than or about 14 nm per minute, less than or about 13 nm per minute, less than or about 12 nm per minute, less than or about 11 nm per minute, less than or about 10 nm per minute, less than or about 9 nm per minute, less than or about 8 nm per minute, less than or about 7 nm per minute, less than or about 6 nm per minute, less than or about 5 nm per minute, less than or about 4 nm per minute, less than or about 3 nm per minute, less than or about 2 nm per minute, less than or about 1 nm per minute, or lower. Again, the etch rate of the silicon dioxide 510 of the embodiments of the present disclosure may allow for fine-tuning of the removal of silicon dioxide 510 and nadir or dish depth of the copper-containing layer 520 can be desirably controlled depending on the final application of the structure. By slowly etching the dielectric film 510, the copper-containing layer 520 may also be more slowly etched. Etching the copper-containing layer 520 at a slower rate may allow the reduced nadir or dish depth, which may make the substrate 505 ideal for copper-to-copper hybrid bonding as explained in the present disclosure.

After operation 410, the copper-containing layer 520 may again be characterized by a concave profile or a dish profile within the one or more features in the dielectric film 510. A nadir of the concave profile, or a dish depth of the dish profile, after operation 410 may be less than or about 5 nm within a surface of the dielectric film 510, and may be less than or about 4 nm, less than or about 3 nm, less than or about 2 nm, less than or about 1 nm, less than or about 0.5 nm, or lower.

A nadir or dish depth of less than 5 nm may be small enough for copper-to-copper hybrid bonding, for example. When the nadir or dish depth is less than 5 nm or lower, subsequent annealing to bond the separate copper elements may be effective as the copper may be close enough to bond to each other during the annealing step. During the annealing step, the copper elements from separate substrates may extrude towards one another, may contact each other, and may bond. At reduced annealing temperatures according to some embodiments of the present technology, unless the dishing is sufficiently reduced, the amount of expansion may be insufficient to allow adequate coupling between the copper. By performing polishing operations according to the present technology, reduce dishing may be provided, which may improve coupling capability between substrates at reduced annealing temperatures.

In some examples, the different operations (for example, operations 202, 204, 206, 208, 210, 402, 404, 406, 408, 410) and subparts of different operations can be done in different chambers of system 100. When a substrate is moved from a first chamber to a second chamber, the substrate is moved without exposing the substrate to an external atmosphere. For example, operation 206 for forming a dielectric film over the dielectric layer can be done in a different chamber than operations 202 and 204 for forming the substrate, metal layer, and dielectric layer. The use of different chambers may be related to different conditions needed for different operations. For example, the chamber for etching the dielectric layer and dielectric film may require special setup due to the special nature of the dielectric material being used for the dielectric film. Similarly, the CMP processes described in relation to operations 402, 404, 406, 408, and 410 may be done in a different chamber than operations 202, 204, and 206.

As used herein, the terms “about” or “approximately” or “substantially” may be interpreted as being within a range that would be expected by one having ordinary skill in the art in light of the specification.

In the foregoing description, for the purposes of explanation, numerous specific details were set forth in order to provide a thorough understanding of various embodiments. It will be apparent, however, that some embodiments may be practiced without some of these specific details. In other instances, well-known structures and devices are shown in block diagram form.

The foregoing description provides exemplary embodiments only, and is not intended to limit the scope, applicability, or configuration of the disclosure. Rather, the foregoing description of various embodiments will provide an enabling disclosure for implementing at least one embodiment. It should be understood that various changes may be made in the function and arrangement of elements without departing from the spirit and scope of some embodiments as set forth in the appended claims.

Specific details are given in the foregoing description to provide a thorough understanding of the embodiments. However, it will be understood that the embodiments may be practiced without these specific details. For example, circuits, systems, networks, processes, and other components may have been shown as components in block diagram form in order not to obscure the embodiments in unnecessary detail. In other instances, well-known circuits, processes, algorithms, structures, and techniques may have been shown without unnecessary detail in order to avoid obscuring the embodiments.

Also, it is noted that individual embodiments may have been described as a process which is depicted as a flowchart, a flow diagram, a data flow diagram, a structure diagram, or a block diagram. Although a flowchart may have described the operations as a sequential process, many of the operations can be performed in parallel or concurrently. In addition, the order of the operations may be re-arranged. A process is terminated when its operations are completed, but could have additional steps not included in a figure. A process may correspond to a method, a function, a procedure, a subroutine, a subprogram, etc. When a process corresponds to a function, its termination can correspond to a return of the function to the calling function or the main function.

The term “computer-readable medium” includes, but is not limited to portable or fixed storage devices, optical storage devices, wireless channels and various other mediums capable of storing, containing, or carrying instruction(s) and/or data. A code segment or machine-executable instructions may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc., may be passed, forwarded, or transmitted via any suitable means including memory sharing, message passing, token passing, network transmission, etc.

Furthermore, embodiments may be implemented by hardware, software, firmware, middleware, microcode, hardware description languages, or any combination thereof. When implemented in software, firmware, middleware or microcode, the program code or code segments to perform the necessary tasks may be stored in a machine readable medium. A processor(s) may perform the necessary tasks.

In the foregoing specification, features are described with reference to specific embodiments thereof, but it should be recognized that not all embodiments are limited thereto. Various features and aspects of some embodiments may be used individually or jointly. Further, embodiments can be utilized in any number of environments and applications beyond those described herein without departing from the broader spirit and scope of the specification. The specification and drawings are, accordingly, to be regarded as illustrative rather than restrictive.

Additionally, for the purposes of illustration, methods were described in a particular order. It should be appreciated that in alternate embodiments, the methods may be performed in a different order than that described. It should also be appreciated that the methods described above may be performed by hardware components or may be embodied in sequences of machine-executable instructions, which may be used to cause a machine, such as a general-purpose or special-purpose processor or logic circuits programmed with the instructions to perform the methods. These machine-executable instructions may be stored on one or more machine readable mediums, such as CD-ROMs or other type of optical disks, floppy diskettes, ROMs, RAMs, EPROMs, EEPROMs, magnetic or optical cards, flash memory, or other types of machine-readable mediums suitable for storing electronic instructions. Alternatively, the methods may be performed by a combination of hardware and software.

What is claimed is:

1. A semiconductor device for hybrid bonding, the semiconductor device comprising:
a first structure comprising:
a metal layer overlaying a substrate;
a dielectric layer overlaying the metal layer and defining a set of one or more features recessed in the dielectric layer;
a dielectric film overlaying the dielectric layer, the dielectric film having a dielectric constant greater than about 7; and
a copper-containing material deposited within the set of one or more features.

2. The semiconductor device of claim 1, further comprising:
a second structure comprising:
a second metal layer overlaying a second substrate;
a second dielectric layer overlaying the second metal layer and defining a second set of one or more features recessed in the second dielectric layer;
a second dielectric film overlaying the second dielectric layer, the second dielectric film having a second dielectric constant greater than about 7; and
a second copper-containing material deposited within the second set of one or more features; and
wherein the dielectric film of the first structure is hybrid bonded to the second dielectric film of the second structure, wherein the copper-containing material of the first structure contacts the second copper-containing material of the second structure.

3. The semiconductor device of claim 1, wherein the dielectric constant is greater than about 8.

4. The semiconductor device of claim 1, wherein the dielectric film has a thickness of 5 nm.

5. The semiconductor device of claim 1, wherein the dielectric film is Al₂O₃.

6. The semiconductor device of claim 1, wherein the copper-containing material is characterized by a dish profile having a dish depth of less than or about 1 nm.

7. A method of forming a semiconductor device, the method comprising:
forming a first structure, wherein forming the first structure comprises:
forming a metal layer over a substrate;
forming a dielectric layer over the metal layer;
forming a dielectric film over the dielectric layer, the dielectric film having a dielectric constant greater than about 7;
etching a trench in the dielectric film and dielectric layer, wherein the trench extends from a top surface of the dielectric film down to at least a top surface of the metal layer; and
filling the trench with a copper-containing material.

8. The method of claim 7, wherein etching the trench in the dielectric film and dielectric layer comprises etching the trench in the dielectric film with a chlorine-based etch.

9. The method of claim 7, wherein etching the trench in the dielectric film and dielectric layer comprises etching the trench in the dielectric film and dielectric layer with a multi-material etch, wherein the multi-material etch comprises two or more of: a chlorine-based etch, a fluorine-based etch, an oxygen-plasma etch, and a fluorine-and-oxygen-based etch.

10. The method of claim 7, wherein forming the metal layer and forming the dielectric layer is performed in a first chamber, wherein etching the trench in the dielectric film and the dielectric layer is performed in a second chamber, wherein the first structure is moved from the first chamber to the second chamber without exposing the substrate to an external atmosphere.

11. The method of claim 7, further comprising contacting the first structure with one or more slurries and one or more platens, wherein the one or more slurries and one or more platens remove a portion of the copper-containing material and a second portion of the dielectric film.

12. The method of claim 11, wherein contacting the first structure with the one or more slurries and one or more platens recesses the copper-containing material a distance of less than or about 1 nm within the trench below a top surface of the dielectric film.

13. The method of claim 12, wherein contacting the first structure with the one or more slurries and one or more platens causes the copper-containing material to be characterized by a dish profile.

14. The method of claim 7, further comprising forming a liner in the trench, and wherein filling the trench with the copper-containing material comprises overlaying the liner with the copper-containing material.

15. The method of claim 7, further comprising:
contacting the first structure with a hydrogen-containing precursor;
contacting the first structure with a second structure, the second structure comprising:
a second metal layer overlaying a second substrate;
a second dielectric layer overlaying the second metal layer and defining a second set of one or more features in the second dielectric layer;
a second dielectric film overlaying the second dielectric layer, the second dielectric film having a second dielectric constant greater than about 7; and
a second copper-containing material deposited within the second set of one or more features; and
bonding the first structure to the second structure, wherein the dielectric film of the first structure is hybrid bonded to the second dielectric film of the second structure, wherein the copper-containing material of the first structure contacts the second copper-containing material of the second structure.

16. The method of claim 15, wherein bonding the first structure to the second structure comprises:
contacting the first structure with water; and
annealing the first structure and the second structure.

17. A method of forming a semiconductor device, the method comprising:
forming a first structure, wherein forming the first structure comprises:
forming a metal layer over a substrate;
forming a barrier film over the metal layer, the barrier film having a dielectric constant of less than or about 5;
forming a tetraethyl orthosilicate layer over the barrier film;
forming a dielectric film over the tetraethyl orthosilicate layer, the dielectric film having a second dielectric constant greater than 7;
etching a trench in the dielectric film, the tetraethyl orthosilicate layer, and the barrier film, wherein the trench extends from a top surface of the dielectric film down to at least a top surface of the metal layer;
forming a liner in the trench; and
filling the trench with a copper-containing material.

18. The method of claim 17, further comprising:
contacting the first structure with a hydrogen-containing precursor;
contacting the first structure with a second structure, the second structure comprising:
a second metal layer overlaying a second substrate;
a second barrier film over the second metal layer, the second barrier film having a third dielectric constant of less than or about 5, the second barrier film defining a second set of one or more features;
a second tetraethyl orthosilicate layer over the second barrier film further defining the second set of one or more features;
a second dielectric film overlaying the second tetraethyl orthosilicate layer, the second dielectric film having a fourth dielectric constant greater than about 7, the second dielectric film further defining the second set of one or more features; and
a second copper-containing material deposited within the second set of one or more features; and
bonding the first structure to the second structure, wherein the dielectric film of the first structure is hybrid bonded to the second dielectric film of the second structure, wherein the copper-containing material of the first structure contacts the second copper-containing material of the second structure.

19. The method of claim 18, wherein bonding the first structure to the second structure comprises:
contacting the first structure with water; and
annealing the first structure and the second structure.

20. The method of claim 18, wherein the second dielectric constant is greater than about 8, wherein the fourth dielectric constant is greater than 8.
